(19) United States
(12) Patent Application Publication
(10) Pub. No.: US 2024/0405155 A1
(43) Pub. Date: Dec. 5, 2024

(54) METHOD FOR TRANSFERRING LIGHT-EMITTING ELEMENT AND METHOD FOR MANUFACTURING LIGHT-EMITTING DEVICE

(71) Applicant: NICHIA CORPORATION, Anan-shi (JP)

(72) Inventors: Nao MORINO, Anan-shi (JP); Takeru TABUCHI, Anan-shi (JP); Hiroaki TAMEMOTO, Anan-shi (JP)

(73) Assignee: NICHIA CORPORATION, Anan-shi (JP)

(21) Appl. No.: 18/658,369

(22) Filed: May 8, 2024

(30) Foreign Application Priority Data
May 30, 2023 (JP) 2023-089137

(51) Int. Cl. H01L 33/00

(52) U.S. Cl. CPC H01L 33/0093

(57) ABSTRACT

A method for transferring a light-emitting element from a first substrate to a second substrate includes: providing the light-emitting element fixed to a first surface of the first substrate via a release layer; and removing the release layer by irradiating the release layer with laser light from a side of the second surface, opposite the first surface, through the first substrate. An intensity distribution of the laser light on the first surface is, in the entire release layer, equal to or higher than a minimum intensity at which the release layer can be removed, and a maximum intensity of the intensity distribution is 150% or less of the minimum intensity.

### CROSS-REFERENCE TO RELATED APPLICATIONS

The present application claims priority under 35 U.S.C. § 119 to Japanese Patent Application No. 2023-089137, filed May 30, 2023, the contents of which are hereby incorporated by reference in their entirety.

### 1. TECHNICAL FIELD

Embodiments of the present disclosure relate to a method for transferring a light-emitting element and a method for manufacturing a light-emitting device.

### 2. DESCRIPTION OF RELATED ART

In a manufacturing process of a light-emitting device, a step of transferring a light-emitting element disposed on a first substrate to a second substrate may be necessary. In such a step, the light-emitting element is required to be reliably transferred (see, e.g., Japanese Patent Publication No. 2010-251359).

### SUMMARY

An object of an embodiment of the present disclosure is to provide a method for transferring a light-emitting element with high reliability and a method for manufacturing a light-emitting device with high reliability.

According to one embodiment, a method for transferring a light-emitting element from a first substrate to a second substrate includes: providing the light-emitting element fixed to a first surface of the first substrate via a release layer; and removing the release layer by irradiating the release layer with laser light from a side of the second surface, opposite the first surface, through the first substrate. An intensity distribution of the laser light on the first surface is, in the entire release layer, equal to or higher than a minimum intensity at which the release layer can be removed, and a maximum intensity of the intensity distribution is 150% or less of the minimum intensity.

According to another embodiment, a method for manufacturing a light-emitting includes a step of transferring the light-emitting element from the first substrate to the second substrate by the above-described method for transferring a light-emitting element.

According to certain embodiments of the present disclosure, it is possible to implement a method for transferring a light-emitting element with high reliability and a method for manufacturing a light-emitting device with high reliability.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a plan view illustrating a first substrate and a second substrate according to an embodiment.

FIG. 2 is a cross-sectional view taken along line II-II illustrated in FIG. 1.

FIG. 3 is a cross-sectional view taken along line III-III illustrated in FIG. 1.

FIG. 4 is a view illustrating a laser optical system used in the embodiment.

FIG. 5 is a cross-sectional view illustrating a step of removing a release layer in the embodiment.

FIG. 6 is a perspective view illustrating a shape and an intensity distribution of laser light with which the release layer is irradiated.

FIG. 7 is a plan view illustrating an intensity distribution of the laser light with which the release layer is irradiated.

FIG. 8 is a view illustrating a relationship between the intensity distribution of the laser light and the release layer.

FIG. 9 is an end view illustrating a method for manufacturing a light-emitting device according to the embodiment.

FIG. 10 is an end view illustrating the method for manufacturing a light-emitting device according to the embodiment.

FIG. 11 is an end view illustrating the method for manufacturing a light-emitting device according to the embodiment.

FIG. 12 is an end view illustrating the method for manufacturing a light-emitting device according to the embodiment.

FIG. 13 is an end view illustrating the method for manufacturing a light-emitting device according to the embodiment.

### DETAILED DESCRIPTION

### Description of Embodiments

A method for transferring a light-emitting element according to an embodiment of the present disclosure will be described below with reference to drawings. The method for transferring a light-emitting element according to the present embodiment is, for example, a part of a method for manufacturing a light-emitting device.

The following description provides examples embodying the technical concepts of the present invention, but the present invention is not limited to the described examples. Dimensions, materials, shapes, relative arrangement, or the like of constituent members described in the embodiments are not intended to limit the scope of the present disclosure thereto, unless otherwise specified, and are merely exemplary. The sizes, positional relationship, or the like of members illustrated in the drawings may be exaggerated for clarity of description. In the following description, the same names and reference numerals denote members that are the same or of the same quality, and a repeated detailed description thereof is omitted as appropriate. As a cross-sectional view, an end view illustrating only a cut surface may be illustrated.

### Step of Preparing Intermediate Structure 50

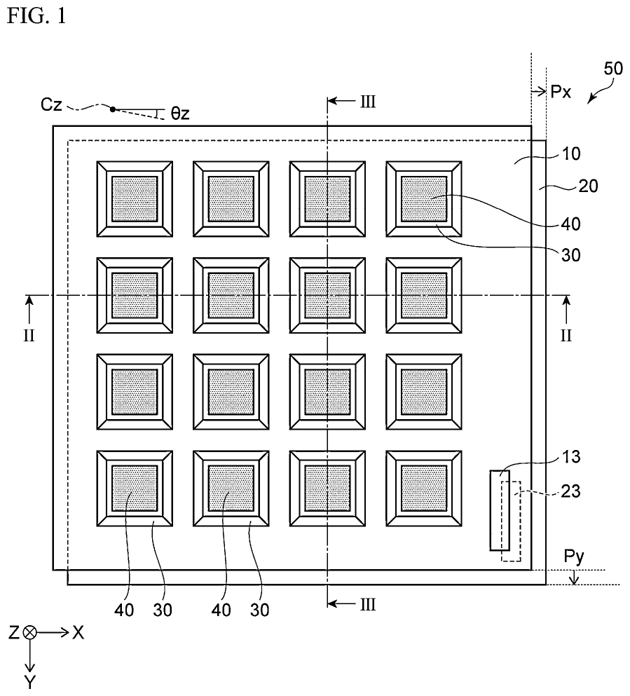

FIG. 1 is a plan view illustrating an intermediate structure in the present embodiment.

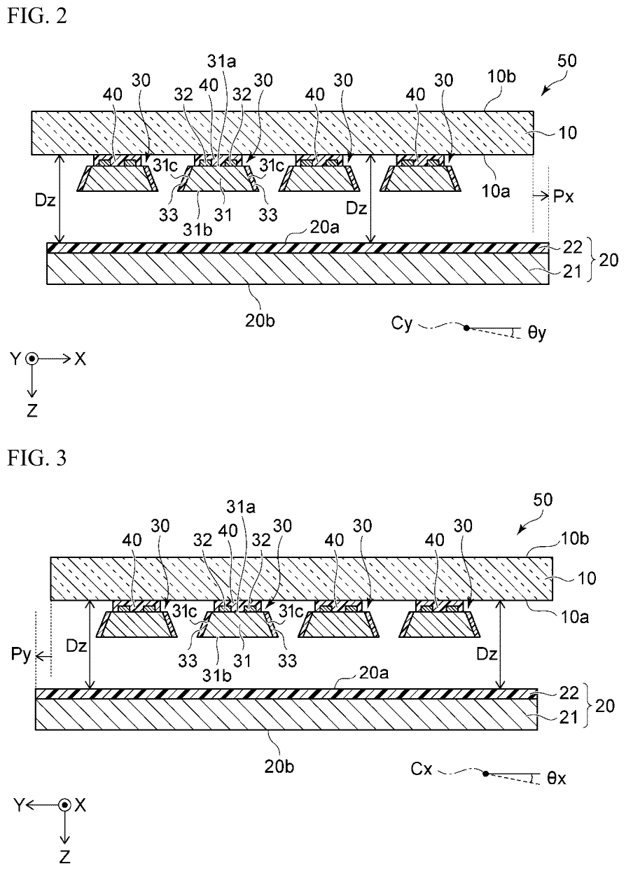

FIG. 2 is a cross-sectional view taken along line II-II illustrated in FIG. 1.

FIG. 3 is a cross-sectional view taken along line III-III illustrated in FIG. 1.

As illustrated in FIGS. 1 to 3, an intermediate structure 50 is prepared. The intermediate structure 50 includes a first substrate 10, a second substrate 20, light-emitting elements 30, and release layers 40. The first substrate 10 is made of a transparent material, such as sapphire, glass, or quartz. A transmittance of laser light (for example, light having a wavelength of 355 nm) in the first substrate 10 is, for example, 75% or more, and preferably 80% or more. The first substrate 10 has a first surface 10a and a second surface 10b on the opposite side of the first surface 10a. Each of the light-emitting elements 30 is fixed to the first surface 10a via a corresponding one of the release layers 40. An alignment portion 13 is disposed on the first surface 10a of the first substrate 10.

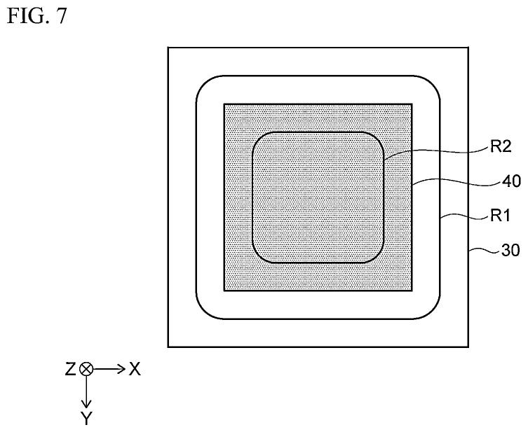

Although FIG. 1 is a view of the first substrate 10 viewed from the second surface 10b side, the first substrate 10 is a light-transmitting substrate, and thus, the release layers 40 and the light-emitting elements 30 are seen through the first substrate 10. Further, in order to make the drawing easy to see, the release layers 40 are illustrated in gray in FIG. 1. The same applies to FIG. 7 described below.

The light-emitting element 30 is, for example, a light-emitting diode (LED). The light-emitting element 30 includes a semiconductor layered body 31 and electrode portions 32. The semiconductor layered body 31 includes a nitride semiconductor such as InₓAl_{y}Ga_{1-x-y}N (0≤x, 0≤y, x+y≤1). The semiconductor layered body 31 includes a p-type layer, an n-type layer, and a light-emitting layer located between the p-type layer and the n-type layer. The light-emitting layer can have, for example, a multi-quantum well structure including a plurality of barrier layers and a plurality of well layers that are alternately layered. The electrode portions 32 include a p-side electrode connected to the p-type layer and an n-side electrode connected to the n-type layer. The light-emitting element 30 according to the present embodiment includes, for example, the p-side electrode and the n-side electrode as the electrode portions 32, and the p-side electrode and the n-side electrode are disposed on the same surface of the semiconductor layered body 31.

In the light-emitting element 30, for example, the electrode portions 32 and the semiconductor layered body 31 are arrayed in order from the release layer 40 side. The semiconductor layered body 31 of the light-emitting element 30 has a first main surface 31a facing the release layer 40, a second main surface 31b on a side opposite the first main surface 31a, and a lateral surface 31c connecting the first main surface 31a and the second main surface 31b. The electrode portions 32 of the light-emitting elements 30 are disposed on the first main surface 31a side of the semiconductor layered body 31. The lateral surface 31c may be provided with a recessed portion or a projected portion.

In the present embodiment, the second main surface 31b of the semiconductor layered body 31 is larger than the first main surface 31a thereof. In other words, in a plan view, an outer shape of the second main surface 31b is located outside the outer shape of the first main surface 31a. The plane area of the second main surface 31b is, for example, in a range from 1.1 times to 2 times, preferably in a range from 1.1 times to 1.5 times, and more preferably in a range from 1.1 times to 1.2 times the plane area of the first main surface 31a. The lateral surface 31c of the semiconductor layered body 31 is inclined so as to spread from the first main surface 31a toward the second main surface 31b. As a result, in the light-emitting element 30 after the transfer, light from the light-emitting layer of the light-emitting element 30 is efficiently reflected by the lateral surface 31c, and is easily extracted from the second main surface 31b which is a light-emitting surface. This improves the light extraction efficiency of the light-emitting device including the light-emitting element 30.

As illustrated in FIGS. 2 and 3, the light-emitting element 30 may include a light attenuating layer 33 on the lateral surface 31c of the semiconductor layered body 31. The light attenuating layer 33 reduces damage to the semiconductor layered body 31 of the light-emitting element 30 due to laser light in a subsequent step of irradiation with the laser light. As described above, the lateral surface 31c of the semiconductor layered body 31 is not a surface perpendicular to the first main surface 31a but is inclined so as to spread in the direction from the first main surface 31a toward the second main surface 31b. In the light-emitting element 30 having such an inclined surface, when the laser light is radiated from the second surface 10b side of the first substrate 10, the lateral surface 31c of the semiconductor layered body 31 is easily irradiated with the laser light. This may damage the semiconductor layered body 31. When the light-emitting element 30 includes the light attenuating layer 33 on the lateral surface 31c of the semiconductor layered body 31, damage to the semiconductor layered body 31 due to the laser light reaching the lateral surface 31c of the semiconductor layered body 31 can be reduced. The light attenuating layer 33 is removed after the light-emitting element 30 is transferred. The light attenuating layer 33 is, for example, a resin member. The light attenuating layer 33 may be, for example, a black resin member. The light attenuating layer 33 can contain, for example, an epoxy resin, an acrylic resin, or a polyimide resin as a main component.

In a plan view, the shape of the light-emitting element 30 is, for example, a square. A length of one side of the first main surface 31a of the semiconductor layered body 31 is, for example, in a range from 10 μm to 100 μm, and may be in a range from 15 μm to 60 μm. In the example illustrated in FIGS. 1 to 3, a plurality of the light-emitting elements 30 are fixed to the first substrate 10 and arrayed in a matrix. The light-emitting elements 30 are separated from each other. The distance between the light-emitting elements 30 is in a range from 3 μm to 100 μm, for example, and is preferably in a range from 3 μm to 20 μm. This can increase the number of the light-emitting elements 30 that can be disposed on the first substrate 10. However, there is no limitation thereto, and one light-emitting element 30 may be fixed to the first substrate 10.

The release layer 40 is provided for each light-emitting element 30. The release layer 40 is located between the first substrate 10 and a corresponding one of the light-emitting elements 30. In a plan view, an outer edge of the release layer 40 is located inside an outer edge of the first main surface 31a of the semiconductor layered body 31 of the light-emitting element 30, and the release layers 40 are separated from each other. In a plan view, by making the planar size of the release layer 40 smaller than the planar size of the first main surface 31a of the semiconductor layered body 31, the irradiation range irradiated with laser light 200 described later can be reduced. This can reduce the possibility that the adjacent release layer 40 other than the release layer 40 to be irradiated is irradiated with the laser light 200. This improves reliability of transfer of the light-emitting element 30.

The release layer 40 is a member that can be removed by the laser light 200. The release layer 40 is, for example, a member that can absorb the laser light 200 to be described below and can be removed by laser ablation, and is, for example, a photosensitive resin. An adhesive layer may be provided between the release layer 40 and the light-emitting element 30. This improves a fixing force for fixing the light-emitting element 30 to the first substrate 10, and thus, the light-emitting element 30 can be reliably irradiated with the laser light in the step of irradiation with the laser light.

The second substrate 20 includes a base material 21 made of, for example, silicon, metal, or glass, and a resin layer 22 made of, for example, a silicone resin. The resin layer 22 is disposed on one surface of the base material 21. The second substrate 20 has a third surface 20a and a fourth surface 20b on the opposite side of the third surface 20a. The resin layer 22 is located on the third surface 20a of the second substrate 20, and the fourth surface 20b is constituted by the base material 21. An alignment portion 23 is disposed on the third surface 20a of the second substrate 20.

### Disposing Step of First Substrate 10 and Second Substrate 20

In the present embodiment, an XYZ orthogonal coordinate system is employed for convenience of explanation. One direction parallel to the first surface 10a of the first substrate 10 is referred to as a “first direction X.” A direction parallel to the first surface 10a of the first substrate 10 and orthogonal to the first direction X is referred to as a “second direction Y.” A direction from the second surface 10b of the first substrate 10 toward the first surface 10a thereof is referred to as a “third direction Z.” The third direction Z is, for example, a vertically downward direction, that is, the direction of gravity. In the present embodiment, the third direction Z is also referred to as “downward,” and the opposite direction thereof is also referred to as “upward.” In this case, an XY plane is a horizontal plane. However, the third direction Z is not limited to the vertically downward direction, and the XY plane is not limited to the horizontal plane. In the present embodiment, the first direction X and the second direction Y are array directions of the light-emitting elements 30.

The first substrate 10 is disposed horizontally with the first surface 10a facing downward. At this stage, the light-emitting element 30 is fixed to the first surface 10a of the first substrate 10 via the release layer 40, and thus the light-emitting element 30 does not fall off from the first substrate 10. Then, the second substrate 20 is disposed below and parallel to the first substrate 10. At this time, the third surface 20a of the second substrate 20 is disposed facing upward. Thus, the third surface 20a of the second substrate 20 faces the first surface 10a of the first substrate 10, and the light-emitting element 30 is disposed between the first substrate 10 and the second substrate 20. In this regard, the light-emitting element 30 is away from the second substrate 20.

At this time, a position Px of the second substrate 20 with respect to the first substrate 10 in the first direction X, a position Py of the second substrate 20 with respect to the first substrate 10 in the second direction Y, and an angle θz of the second substrate 20 with respect to the first substrate 10 with a straight line extending in the third direction Z as a rotation axis Cz are adjusted with reference to the alignment portion 13 provided on the first substrate 10 and the alignment portion 23 provided on the second substrate 20. The angle θz is, for example, in a range from 0 degrees to 3 degrees, and preferably in a range from 0 degrees to 2 degrees.

A distance Dz to the second substrate 20 from the first substrate 10 in the third direction Z, an angle θx of the second substrate 20 with respect to the first substrate 10 with a straight line extending in the first direction X as a rotation axis Cx, and an angle θy of the second substrate 20 with respect to the first substrate 10 with a straight line extending in the second direction Y as a rotation axis Cy are adjusted by measuring a distance Dz between the first substrate 10 and the second substrate 20 at two or more points, preferably three or more points. The distance Dz is set, for example, in a range from 20 μm to 40 μm. The angle θx and the angle θy are, for example, in a range from 0 degrees to 3 degrees, and preferably in a range from 0 degrees to 2 degrees.

In the present embodiment, the positional relationship between the first substrate 10 and the second substrate 20 is adjusted by fixing the first substrate 10 and moving the second substrate 20 or adjusting an arrangement angle of the second substrate 20. The method for transferring the light-emitting element of the present disclosure is not limited thereto, and the second substrate 20 may be fixed and the first substrate 10 may be moved or the arrangement angle of the first substrate 10 may be adjusted. In addition, both the first substrate 10 and the second substrate 20 may be moved or the arrangement angles thereof may be adjusted.

### Step of Removing Release Layer

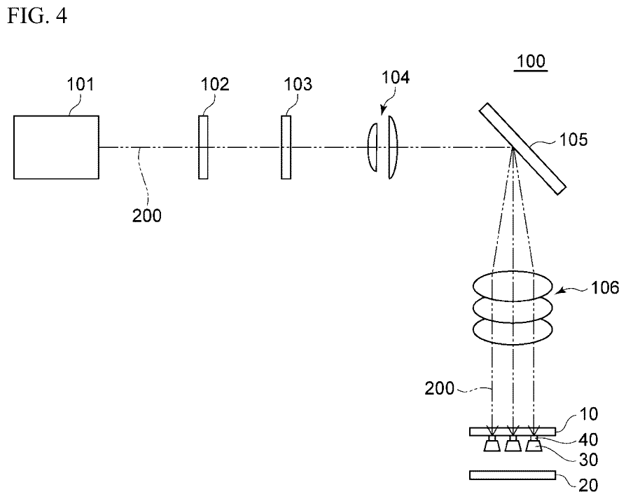

FIG. 4 is a view illustrating a laser optical system used in the present embodiment.

As illustrated in FIG. 4, a laser optical system 100 in the present embodiment includes a laser light source 101, an attenuator 102, a diffractive optical element (DOE) 103, a beam expander mechanism 104, a galvanometer mirror 105, and a telecentric lens 106. The release layer 40 is removed by the laser light 200 in the laser optical system 100. The laser light source 101 emits the laser light 200. The laser light source 101 is, for example, a medium to long wavelength laser light source. A wavelength of the laser light 200 is not particularly limited, but is, for example, in a range from 250 nm to 400 nm. As an example, the laser light 200 is light having a wavelength of about 355 nm. When the laser light 200 is emitted from the laser light source 101, the shape of the laser light 200 is circular. The “shape of the laser light” means a shape of a region irradiated with the laser light in a plane perpendicular to a traveling direction of the laser light. When the laser light 200 is emitted from the laser light source 101, an intensity distribution of the laser light 200 is a Gaussian distribution. In the intensity distribution of the laser light having the Gaussian distribution, for example, when the intensity at which the release layer 40 can be removed, is the minimum intensity, the maximum intensity is 200% or more of the minimum intensity. The attenuator 102, the diffractive optical element 103, the beam expander mechanism 104, the galvanometer mirror 105, and the telecentric lens 106 described above are disposed along a path of the laser light 200.

The attenuator 102 attenuates the laser light 200 emitted from the laser light source 101. The attenuator 102 need not be provided. The diffractive optical element 103 is an element having a light intensity conversion function, and converts the shape of the laser light 200 from a circular shape to a rectangular shape such as a square shape, and converts the intensity distribution of the laser light 200 from the Gaussian distribution to a top-hat type distribution. The beam expander mechanism 104 adjusts the irradiation range irradiated with the laser light 200 in accordance with the planar size of the release layer 40. By the diffractive optical element 103 and the beam expander mechanism 104, the shape of the laser light 200 and the irradiation range irradiated with the laser light 200 become a shape and an irradiation range corresponding to the release layer 40.

The galvanometer mirror 105 controls a direction in which the laser light 200 is reflected by changing an angle with respect to the traveling direction of the laser light 200. It is possible to irradiate a specific light-emitting element with laser light by changing an angle of the galvanometer mirror 105, so that it is possible to shorten the time required for laser light irradiation as compared with, for example, a laser irradiation device that emits laser light while moving a nozzle. The telecentric lens 106 is, for example, a telecentric fθ lens. The telecentric lens 106 has a role of bringing the traveling directions of the laser lights 200 incident from the galvanometer mirror 105 close to the same direction. By the galvanometer mirror 105 and the telecentric lens 106, only an irradiation position of the laser light 200 can be selected without largely changing the traveling direction of the laser light 200. Thus, a specific light-emitting element fixed to the first substrate 10 can be selectively irradiated with the laser light 200.

An angle formed by the traveling direction of the laser light 200 having exited from the telecentric lens 106 with respect to an optical axis of the telecentric lens 106 is preferably 5 degrees or less, more preferably 3 degrees or less, and still more preferably 1 degree or less. The optical axis of the telecentric lens 106 extends, for example, in the third direction Z.

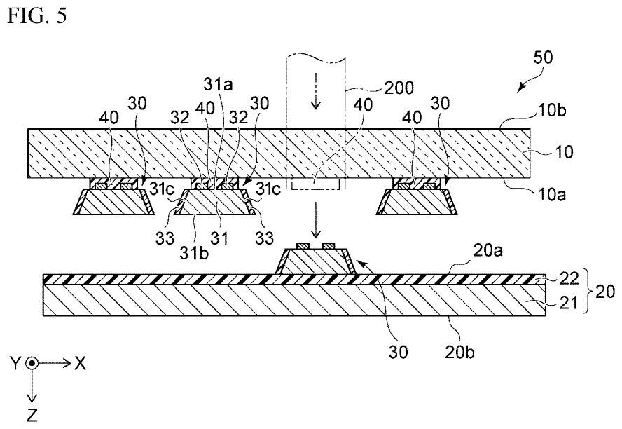

FIG. 5 is a cross-sectional view illustrating a step of removing the release layer in the present embodiment.

As illustrated in FIG. 5, the laser light 200 having exited from the telecentric lens 106 is incident on the first substrate 10. At this time, the first substrate 10, the second substrate 20, the light-emitting element 30, and the release layer 40 are in the positional relationship described above. The laser light 200 is incident from the second surface 10b of the first substrate 10, travels in the first substrate 10, exits from the first surface 10a, and is radiated to a selected one of the release layers 40. In this manner, the release layer 40 is irradiated with the laser light 200 through the first substrate 10. The release layer 40 irradiated with the laser light 200 absorbs the laser light 200 and is removed by laser ablation, for example. As an example, bonding between molecules forming the release layer 40 is released by the energy of the laser light 200, and thus the release layer 40 is sublimated. As a result, the release layer 40 which has been a solid becomes a gas and the release layer 40 is removed. A phenomenon used to remove the release layer 40 is not limited to sublimation.

By removing the release layer 40, the fixation between the light-emitting element 30 and the first substrate 10 is released. When the release layer 40 is sublimated, the release layer 40 which has been the solid becomes the gas, so that a volume thereof is expanded and a pressure is generated. By this pressure, the light-emitting element 30 is biased in a direction away from the first substrate 10. Thus, the light-emitting element 30 moves in the air in the third direction Z from the first substrate 10 toward the second substrate 20 and reaches the resin layer 22. The resin layer 22 has tackiness, and thus the light-emitting element 30 is fixed to the third surface 20a of the second substrate 20 by the resin layer 22.

Then, by controlling the laser light source 101 and the galvanometer mirror 105, a plurality of the release layers 40 are sequentially irradiated with the laser light 200. Thus, the plurality of light-emitting elements 30 are transferred from the first substrate 10 to the second substrate 20.

### Shape and Intensity Distribution of Laser Light 200

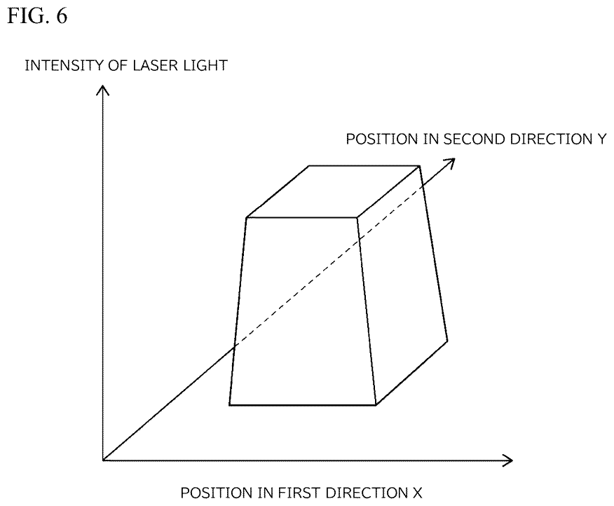

FIG. 6 is a perspective view illustrating a shape and an intensity distribution of the laser light with which the release layer is irradiated.

FIG. 7 is a plan view illustrating an intensity distribution of the laser light with which the release layer is irradiated.

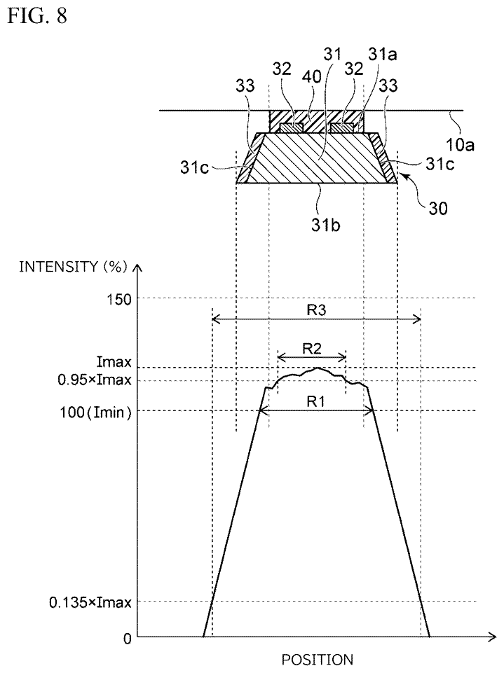

FIG. 8 is a view illustrating a relationship between the intensity distribution of the laser light and the release layer.

The lower part of FIG. 8 is a graph showing the intensity distribution of the laser light with the horizontal axis representing a position in the first direction X and the vertical axis representing the intensity of the laser light. In the upper part of FIG. 8, positions of the light-emitting element and the release layer are illustrated so as to correspond to the graph in the lower part.

As illustrated in FIGS. 6 to 8, the shape of the laser light 200 on the first surface 10a of the first substrate 10 is a rectangular shape slightly larger than the release layer 40, and the intensity distribution thereof is a top-hat type. The intensity distribution of the laser light 200 on the first surface 10a is, in the entire release layer 40, equal to or higher than the minimum intensity Imin at which the release layer 40 can be removed. The minimum intensity Imin at which the release layer 40 can be removed is, for example, the minimum intensity at which the release layer 40 can be sublimated, and is substantially uniquely determined when a material of the release layer 40 and the wavelength of the laser light 200 are determined. Hereinafter, the minimum intensity Imin at which the release layer 40 can be removed is used as a reference, and this intensity is set as “100%.” The maximum intensity Imax of the laser light 200 is 150% or less of the minimum intensity Imin. The maximum intensity Imax of the laser light 200 is preferably 130% or less, more preferably 110% or less of the minimum intensity Imin.

As illustrated in FIGS. 7 and 8, in a plan view, the outer edge of the release layer 40 is located inside the outer edge of the light-emitting element 30. Specifically, in a plan view, the outer edge of the release layer 40 is located inside the outer edge of the first main surface 31a of the semiconductor layered body 31 of the light-emitting element 30. A first region R1 on the first surface 10a of the first substrate 10 in which the intensity of the laser light 200 is the minimum intensity Imin or more is located inside the light-emitting element 30. The release layer 40 is located inside the first region R1. When the plurality of light-emitting elements 30 are provided on the first substrate 10 with the respective release layers 40 interposed therebetween, and the plurality of light-emitting elements 30 are disposed close to each other, in addition to the release layer 40 to be irradiated, the adjacent release layer 40 may also be irradiated with the laser light 200. However, in a plan view, by making the planar size of the release layer 40 smaller than the planar size of the light-emitting element 30 and making the first region R1 in which the intensity of the laser light 200 is the minimum intensity Imin or more smaller than the planar size of the light-emitting element 30, even when the adjacent release layer 40 is irradiated with the laser light 200, the likelihood of removal of the adjacent release layer 40 can be reduced. Thus, the reliability of the transfer of the light-emitting element 30 can be increased.

A second region R2 in which the intensity of the laser light 200 on the first surface 10a is 95% or more of the maximum intensity Imax is preferably located inside the release layer 40. This makes it easy to reduce damage to the light-emitting element 30 due to the laser light 200. A length of the second region R2 is, for example, 50% or more, preferably 60% or more of a length of the first region R1 in a direction parallel to the first surface 10a, that is, a direction parallel to the XY plane. A length of a third region R3 on the first surface 10a in which the intensity of the laser light 200 is 13.5% or more of the maximum intensity Imax is, for example, 250% or less, preferably 200% or less of the length of the first region R1. Thus, the laser light 200 having a top-hat type intensity distribution in which unevenness of the intensity distribution is reduced can be formed, and the light-emitting element 30 can be transferred with high positional accuracy.

A transmittance for the laser light 200 of the first substrate 10 is preferably higher than a transmittance for the laser light 200 of the release layer 40. In other words, it is preferable that most of the laser light 200 is transmitted through the first substrate 10 and is less likely to be transmitted through and is more likely to be absorbed by the release layer 40. Specifically, the transmittance for the laser light 200 of the release layer 40 is, for example, 70% or less, preferably 60% or less of the transmittance for the laser light 200 of the first substrate 10. The transmittance for the laser light 200 of the release layer 40 is preferably in a range from 40% to 60%. By setting the transmittances of the first substrate 10 and the release layer 40 as described above, the laser light 200 is easily transmitted through the inside of the first substrate 10, and the release layer 40 easily absorbs the energy of the laser light 200. This improves accuracy of removal of the release layer 40, and can improve the reliability of the transfer of the light-emitting element 30.

It is preferable that the laser light 200 can maintain the above-described intensity distribution over the entire thickness of the release layer 40. When it is assumed that the transmittance for the laser light 200 of the release layer 40 is 100%, that is, when it is assumed that the release layer 40 does not absorb the laser light 200 at all, the intensity distribution of the laser light 200 on the surface of the release layer 40 on the light-emitting element 30 side is, in the entire release layer 40, preferably the minimum intensity Imin or more, and the maximum intensity Imax of the intensity distribution is preferably 150% or less of the minimum intensity Imin. The maximum intensity Imax is preferably 130% or less, more preferably 110% or less of the minimum intensity Imin.

When it is assumed that the transmittance for the laser light 200 of the release layer 40 is 100%, the thickness of the release layer 40 with respect to a focal depth of the laser light 200 in the third direction Z is preferably in a range from 0.01% to 0.1%. In the present embodiment, the “focal depth of the laser light 200” is a range in the third direction Z that allows the XY plane in which the laser light 200 has the above-described intensity distribution, that is, the intensity distribution is, in the entire release layer 40, the minimum intensity Imin or more and the maximum intensity Imax of the intensity distribution is 150% or less of the minimum intensity Imin. In an example, the focal depth of the laser light 200 is in a range from 400 μm to 800 μm. In this case, the thickness of the release layer 40 is preferably in a range from 40 nm to 800 nm.

### Method for Manufacturing Light-Emitting Device

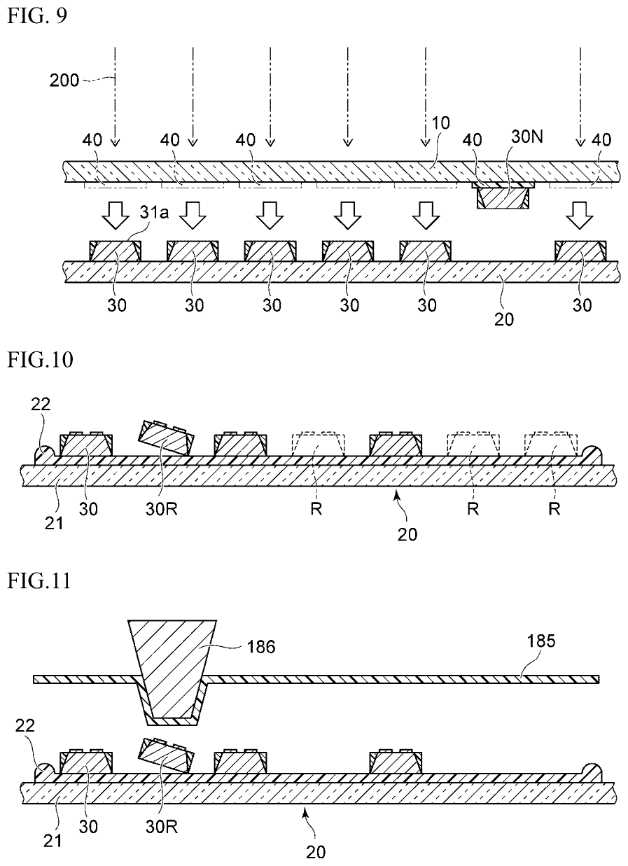

The method for transferring a light-emitting element according to the present embodiment can be applied to a method for manufacturing a light-emitting device. FIGS. 9 to 13 are end views illustrating the method for manufacturing a light-emitting device according to the present embodiment.

As illustrated in FIG. 9, in the laser light 200 irradiation step, some of the light-emitting elements 30 need not be irradiated with laser light. Specifically, the step of manufacturing the light-emitting device may include a step of inspecting each of the light-emitting elements 30 illustrated in FIGS. 1 to 3 and detecting a defective light-emitting element 30N by the inspection before the step of transferring the light-emitting element 30 from the first substrate 10 to the second substrate 20, and in the step of the transfer, the release layers 40 other than a release layer 40 corresponding to the light-emitting element 30N determined to be defective in characteristics by the inspection may be irradiated with the laser light 200.

The inspection may be an appearance inspection for inspecting the appearance of the light-emitting element 30 or an electrical characteristic evaluation for evaluating the electrical characteristics of the light-emitting element 30. Thus, the defective light-emitting element 30N is not transferred, and only non-defective light-emitting elements 30 can be transferred. In this way, since the light-emitting element 30N determined to be defective in the appearance inspection or the like can be removed, only non-defective light-emitting elements 30 can be used in a subsequent step.

The step of manufacturing the light-emitting device may further include a rework process after the step of transferring the light-emitting elements 30. The rework process includes a step of inspecting the transfer state of the light-emitting elements 30 on the second substrate 20 after the transfer and detecting a light-emitting element 30R in a defective transfer state or a region R in which no light-emitting element 30 is disposed, a step of, when there is the light-emitting element 30R in a defective transfer state, removing the light-emitting element 30R, and a step of disposing a new light-emitting element 30 in a region in which the removed light-emitting element 30R has been disposed or the region R in which the light-emitting element 30 is not disposed.

Specifically, as illustrated in FIG. 10, the transfer state of the light-emitting elements 30 on the second substrate 20 after the transfer is inspected, and the light-emitting element 30R in the defective transfer state or the region R in which no light-emitting element 30 is disposed is detected. The light-emitting element 30R in the defective transfer state may be a light-emitting element whose position after the transfer is shifted from a reference position in any direction. The region R is a region in which the light-emitting element 30 is supposed to be disposed, but in which no light-emitting element 30 is actually disposed. First, the light-emitting element 30R in a defective transfer state and the region R are detected by appearance inspection.

Subsequently, when the light-emitting elements 30 include the light-emitting element 30R in a defective transfer state, the light-emitting element 30R in a defective transfer state is removed as illustrated in FIG. 11. In a method for removing the light-emitting element 30R, for example, a pressing portion 186 is pressed against the light-emitting element 30R via an adhesive sheet 185, whereby the light-emitting element 30R is bonded to the adhesive sheet 185. Subsequently, the pressing portion 186 and the adhesive sheet 185 are separated from the second substrate 20. Thus, the light-emitting element 30R is removed from the second substrate 20 together with the adhesive sheet 185.

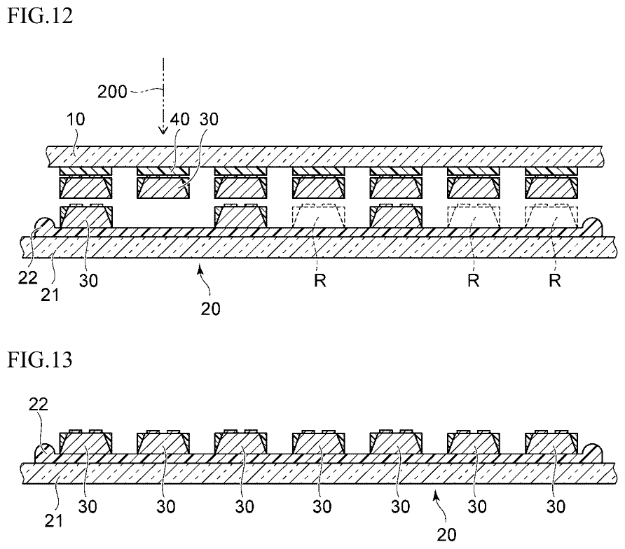

Subsequently, as illustrated in FIG. 12, a new light-emitting element 30 is disposed in the region in which the removed light-emitting element 30R has been disposed or in the region R. In a method for disposing the new light-emitting element 30, for example, a structure in which the new light-emitting element 30 is disposed on the first substrate 10 is prepared, and the light-emitting element 30 corresponding to the region in which the light-emitting element 30R has been disposed or the region R is irradiated with the laser light 200 to transfer the light-emitting element 30 again. Thus, as illustrated in FIG. 13, non-defective light-emitting elements 30 are disposed in all the regions on the second substrate 20 in which the light-emitting elements 30 are to be disposed.

### Effect

Next, an effect of the present embodiment will be described.

In the present embodiment, the release layer 40 is removed by being irradiated with the laser light 200. Thus, among the plurality of light-emitting elements 30 fixed to the first substrate 10, only the selected light-emitting element 30 can be transferred from the first substrate 10 to the second substrate 20. In the present embodiment, the release layer 40 may be removed by being sublimated. By sublimating and removing the release layer 40, the light-emitting element 30 is biased in a direction away from the first substrate 10 by pressure due to volume expansion of the release layer 40 becoming from a solid to a gas. Thus, the light-emitting element 30 is reliably transferred onto the second substrate 20.

In the present embodiment, the intensity distribution of the laser light 200 on the first surface 10a of the first substrate 10 is, in the entire release layer 40, set to the minimum intensity Imin or more. Thus, the entire release layer 40 can be sublimated. On the other hand, the maximum intensity Imax of the laser light 200 is set to 150% or less of the minimum intensity Imin. Thus, the intensity distribution of the laser light 200 with which the release layer 40 is irradiated becomes nearly uniform, and the likelihood of a part of the release layer 40 being sublimated before the other portion can be reduced. Thus, the method for transferring a light-emitting element according to the present embodiment has high reliability.

If the intensity distribution of the laser light 200 with which the release layer 40 is irradiated is not uniform and there is a portion where the maximum intensity Imax is 150% or more of the minimum intensity Imin, a portion of the release layer 40 may be sublimated first while the other portion of the release layer 40 is not sublimated. In this case, in a state where the light-emitting element 30 is bonded to an unsublimated portion of the release layer 40, the light-emitting element 30 is biased by pressure of the gas derived from the sublimated portion of the release layer 40. As a result, the light-emitting element 30 may move in an unexpected direction. This reduces the reliability of the transfer of the light-emitting elements 30 from the first substrate 10 to the second substrate 20.

In the present embodiment, the transmittance for the laser light 200 of the release layer 40 is set to be in a range from 40% to 60%. By setting the transmittance for the laser light 200 of the release layer 40 to 40% or more, the laser light 200 reaches not only a portion of the release layer 40 on the first substrate 10 side but also a portion of the release layer 40 on the light-emitting element 30 side, and the release layer 40 is easily sublimated uniformly in the thickness direction. In addition, by setting the transmittance to 60% or less, the laser light 200 can be sufficiently absorbed in the release layer 40 to efficiently sublimate the release layer 40 and damage to the light-emitting element 30 due to the laser light 200 can be reduced.

In the present embodiment, the second region R2 in which the intensity of the laser light 200 is 95% or more of the maximum intensity Imax is located inside the release layer 40. This makes it easy to reduce damage to the light-emitting element 30 due to the laser light 200 passing through the lateral side of the release layer 40.

In the present embodiment, the transmittance for the laser light 200 of the release layer 40 is set to 70% or less of the transmittance for the laser light 200 of the first substrate 10. Thus, most of the laser light 200 is absorbed not by the first substrate 10 but by the release layer 40, and the release layer 40 can be efficiently sublimated.

In the present embodiment, when it is assumed that the transmittance for the laser light 200 of the release layer 40 is 100%, the intensity distribution of the laser light 200 on the surface of the release layer 40 on the light-emitting element 30 side is also, in the entire release layer 40, the minimum intensity Imin or more, and the maximum intensity Imax of the intensity distribution is 150% or less of the minimum intensity Imin. Thus, the laser light 200 can maintain the above-described intensity distribution over the entire thickness of the release layer 40, and the entire release layer 40 can be sublimated more reliably.

In the present embodiment, the thickness of the release layer 40 with respect to the focal depth of the laser light 200 is set in a range from 0.01% to 0.1%. In other words, the laser optical system 100 is set such that the focal depth is in a range from 1000 times to 10000 times of the thickness of the release layer 40. This enables a sufficient focal depth, and the release layer 40 can be stably sublimated. As a result, the reliability of the transfer of the light-emitting element 30 is improved.

Further, in the present embodiment, the traveling direction of the laser light 200 having exited from the telecentric lens 106 is set to 5 degrees or less with respect to the optical axis of the telecentric lens 106. Thus, all the release layers 40 can be irradiated with the laser light 200 from substantially the same direction. As a result, the shape and the intensity distribution of the laser light 200 can be substantially the same with respect to all the release layers 40. This also improves the reliability of the transfer of the light-emitting element 30. Further, by setting the traveling direction of the laser light 200 with respect to the optical axis of the telecentric lens 106 to 3 degrees or less, and more preferably 1 degree or less, the degree of freedom of each of parameters of other members of the laser optical system 100 is increased.

The method for transferring a light-emitting element according to the present embodiment can be applied to the method for manufacturing a light-emitting device. That is, the method for manufacturing the light-emitting device can include the step of transferring the light-emitting element. The method for manufacturing the light-emitting device may include, in addition to the step of transferring the light-emitting element, for example, a step of disposing a phosphor layer on the transferred light-emitting element and/or a step of collectively holding the plurality of light-emitting elements with a light shielding member having a light-reflecting property or a light-absorbing property. When the method for manufacturing the light-emitting device includes the step of transferring the light-emitting element, the productivity of the light-emitting device is improved. Further, as described above, since the method for transferring the light-emitting element according to the present embodiment has high reliability, the yield of the light-emitting device is improved.

The above-described embodiments have been presented as examples embodying the present invention, but the scope of the invention is not intended to be limited to the described embodiments. For example, additions, deletions, or changes of some components or steps in the aforementioned embodiments are also included in the scope of the present invention.

1. A method for transferring a light-emitting element from a first substrate to a second substrate, the method comprising:
providing the light-emitting element fixed to a first surface of the first substrate via a release layer; and
removing the release layer by irradiating the release layer with laser light from a side of the second surface, opposite the first surface, through the first substrate, wherein:
an intensity distribution of the laser light on the first surface is, in the entire release layer, equal to or higher than a minimum intensity at which the release layer can be removed, and a maximum intensity of the intensity distribution is 150% or less of the minimum intensity.

2. The method for transferring a light-emitting element according to claim 1, wherein:
a transmittance for the laser light of the release layer is in a range from 40% to 60%.

3. The method for transferring a light-emitting element according to claim 1, wherein:
a transmittance for the laser light of the release layer is 70% or less of a transmittance for the laser light of the first substrate.

4. The method for transferring a light-emitting element, according to claim 1, wherein:
in a plan view, an outer edge of the release layer is located inside an outer edge of the light-emitting element, a first region on the first surface in which an intensity of the laser light is the minimum intensity or more is located inside the light-emitting element, and a second region on the first surface in which the intensity of the laser light is 95% or more of the maximum intensity is located inside the release layer.

5. The method for transferring a light-emitting element according to claim 4, wherein:
a length of the second region is in a range from 50% to 80% of a length of the first region in a direction parallel to the first surface.

6. The method for transferring a light-emitting element according to claim 1, wherein:
assuming that a transmittance for the laser light of the release layer is 100%, the intensity distribution of the laser light on a surface of the release layer on a side of the light-emitting element is the minimum intensity or more in the entire release layer, and the maximum intensity of the intensity distribution is 150% or less of the minimum intensity.

7. The method for transferring a light-emitting element, according to claim 1, wherein:
assuming that a transmittance for the laser light of the release layer is 100%, a thickness of the release layer is in a range from 0.01% to 0.1% with respect to a focal depth that allows a plane in which the intensity distribution of the laser light is, in the entire release layer, the minimum intensity or more and the maximum intensity of the intensity distribution is 150% or less of the minimum intensity, in a direction from the second surface toward the first surface.

8. The method for transferring a light-emitting element according to claim 1, further comprising:
disposing the second substrate parallel to the first substrate before the removing the release layer, wherein (i) a position of the second substrate with respect to the first substrate in a first direction parallel to the first surface and a second direction parallel to the first surface and inclined with respect to the first direction, and (ii) an angle of the second substrate with respect to the first substrate with a straight line extending in a third direction from the second surface toward the first surface as a rotation axis, are adjusted with reference to alignment portions provided respectively on the first substrate and the second substrate.

9. The method for transferring a light-emitting element according to claim 8, wherein:
in the step of disposing the second substrate parallel to the first substrate, (i) a distance to the second substrate from the first substrate in the third direction, (i) an angle of the second substrate with respect to the first substrate with a straight line extending in the first direction as a rotation axis, and (iii) an angle of the second substrate with respect to the first substrate with a straight line extending in the second direction as a rotation axis, are adjusted by measuring a distance between the first substrate and the second substrate at two or more points.

10. The method for transferring a light-emitting element according to claim 1, wherein:
the laser light is emitted from a laser light source, is diffracted by a diffraction grating, is expanded in diameter by a beam expander mechanism, has an optical path selected by a galvanometer mirror, is collimated by a telecentric lens, and is incident on the first substrate.

11. The method for transferring a light-emitting element according to claim 10, wherein:
an angle formed by a traveling direction of the laser light having exited from the telecentric lens with respect to an optical axis of the telecentric lens is 1 degree or less.

12. A method for manufacturing a light-emitting device, the method comprising:
transferring the light-emitting element from the first substrate to the second substrate by the method according to claim 1.
